(19) United States
(12) Patent Application Publication
(10) Pub. No.: US 2022/0375731 A1
(43) Pub. Date: Nov. 24, 2022

(54) SUBSTRATE SUPPORT, PLASMA PROCESSING APPARATUS, AND PLASMA PROCESSING METHOD

(71) Applicant: Tokyo Electron Limited, Tokyo (JP)

(72) Inventors: Chishio KOSHIMIZU, Miyagi (JP); Shoichiro MATSUYAMA, Miyagi (JP)

(73) Assignee: Tokyo Electron Limited, Tokyo (JP)

(21) Appl. No.: 17/746,958

(22) Filed: May 18, 2022

(30) Foreign Application Priority Data
May 19, 2021 (JP) 2021-084760

(51) Int. Cl. H01J 37/32

(52) U.S. Cl. CPC H01J 37/32715; H01J 37/32568; H01J 37/32082; H01J 37/32642; H01J 2237/2007

(57) ABSTRACT

A substrate support disclosed herein includes a base and an electrostatic chuck (ESC). The ESC is located on the base. The base and the electrostatic chuck provide a first region configured to support a substrate and a second region extending to surround the first region and configured to support an edge ring. The first region or the second region includes a variable capacitor portion configured to have variable electrostatic capacitance.

### CROSS-REFERENCE TO RELATED APPLICATION

This application claims priority to Japanese Patent Application No. 2021-084760, filed on May 19, 2021, the entire contents of which are incorporated herein by reference.

### TECHNICAL FIELD

Exemplary embodiments of the present disclosure relate to a substrate support, a plasma processing apparatus, and a plasma processing method.

### BACKGROUND

A plasma processing apparatus is used in plasma processing with respect to a substrate. The plasma processing apparatus includes a chamber and a substrate support. The substrate support includes a base and an electrostatic chuck (ESC) and is provided in the chamber. The ESC is located on the base. The substrate support supports the substrate and an edge ring placed on the substrate support.

Such a plasma processing apparatus is disclosed in Patent Literature 1 described below.

### PRIOR ART DOCUMENTS

### Patent Documents

### [Patent Document 1]

### Japanese Patent Application Publication No. 2021-044413

### SUMMARY

### Technical Problems

Among other things, the present disclosure provides a technique capable of relatively adjusting the state of plasma on a substrate and the state of plasma on an edge ring.

### Solutions to Problems

In one exemplary embodiment, a substrate support is provided. The substrate support includes a base and an electrostatic chuck. The ESC is located on the base. The base and the electrostatic chuck provide a first region configured to support a substrate and a second region extending to surround the first region and configured to support an edge ring. The first region or the second region includes a variable capacitor portion configured to provide variable electrostatic capacitance.

### Advantageous Effects

According to one exemplary embodiment, the state of plasma on a substrate and the state of plasma on an edge ring can be adjusted relative to one another (relatively adjusted).

### BRIEF DESCRIPTION OF DRAWINGS

FIG. 1 is a diagram schematically showing a plasma processing apparatus according to an exemplary embodiment.

FIG. 2 is a diagram schematically illustrating a plasma processing apparatus according to an exemplary embodiment.

FIG. 3 is a diagram illustrating a substrate support according to an exemplary embodiment.

FIG. 4 is a diagram illustrating a substrate support according to another exemplary embodiment.

FIG. 5 is a diagram illustrating a substrate support according to still another exemplary embodiment.

FIG. 6 is a diagram illustrating a substrate support according to still another exemplary embodiment.

FIG. 7 is a diagram illustrating a substrate support according to still another exemplary embodiment.

FIG. 8 is a diagram illustrating a substrate support according to still another exemplary embodiment.

FIG. 9 is a diagram illustrating a substrate support according to still another exemplary embodiment.

FIG. 10 is a diagram illustrating a substrate support according to still another exemplary embodiment.

FIG. 11 is a diagram illustrating a substrate support according to still another exemplary embodiment.

FIG. 12 is a diagram illustrating a substrate support according to still another exemplary embodiment.

FIG. 13 is a diagram illustrating a substrate support according to still another exemplary embodiment.

FIG. 14 is a diagram illustrating a substrate support according to still another exemplary embodiment.

FIG. 15 is a diagram illustrating a substrate support according to still another exemplary embodiment.

FIG. 16 is a flowchart of a plasma processing method according to an exemplary embodiment.

### DETAILED DESCRIPTION

Hereinafter, various exemplary embodiments will be described.

In one exemplary embodiment, a substrate support is provided. The substrate support includes a base and an electrostatic chuck (ESC) that is located on the base. The base and the electrostatic chuck provide a first region configured to support a substrate and a second region extending to surround the first region and configured to support an edge ring. At least one of the first region and the second region includes a variable capacitor portion configured to have variable electrostatic capacitance.

In the embodiment described above, it is possible to relatively adjust the electrostatic capacitance of the substrate support below the substrate and the electrostatic capacitance of the substrate support below the edge ring. Therefore, the state of the plasma on the substrate and the state of the plasma on the edge ring can be adjusted relative to one another.

In one exemplary embodiment, the variable capacitor portion may be a cavity provided in the electrostatic chuck. The variable capacitor portion is connected to a supply configured to supply a fluid to the variable capacitor portion and adjust the amount of the fluid in the variable capacitor portion. In one exemplary embodiment, the variable capacitor portion may include a pair of comb-tooth electrodes provided so as to be spaced apart from each other in the cavity.

In one exemplary embodiment, the variable capacitor portion may provide one or more cavities. The variable capacitor portion may include one or more conductor portions provided so as to be movable along a thickness direction of the electrostatic chuck within one or more cavities. The one or more conductor portions may be connected to one or more actuators that move the one or more conductor portions along the thickness direction.

In one exemplary embodiment, the variable capacitor portion is a first variable capacitor portion provided in the first region. The second region may include a second variable capacitor portion.

The second variable capacitor portion is provided in the second region, and configured to have variable electrostatic capacitance

In one exemplary embodiment, the first variable capacitor portion may be a cavity provided in the electrostatic chuck, and may be connected to a first supply configured to supply the fluid to the first variable capacitor portion and adjust the amount of fluid in the first variable capacitor portion. The second variable capacitor portion may be a cavity provided in the electrostatic chuck, and may be connected to a second supply configured to supply the fluid to the second variable capacitor portion and adjust the amount of fluid in the second variable capacitor portion.

In one exemplary embodiment, the first variable capacitor portion may provide one or more first cavities. The first variable capacitor portion may include one or more first conductor portions provided so as to be movable along the thickness direction of the electrostatic chuck within the one or more first cavities. The one or more first conductor portions may be connected to one or more first actuators that move the one or more first conductor portions along the above direction.

The second variable capacitor portion may provide one or more second cavities. The second variable capacitor portion may include one or more second conductor portions provided so as to be movable along the above direction within the one or more second cavities. The one or more second conductor portions may be connected to one or more second actuators that move the one or more second conductor portions along the above direction.

In one exemplary embodiment, a thickness of the electrostatic chuck in the first region may be larger than a thickness of the electrostatic chuck in the second region.

In one exemplary embodiment, the base may be formed of metal.

In one exemplary embodiment, the base may include a base part, a first electrode film, and a second electrode film. The base part is formed of an insulator. The first electrode film is provided below the first region and on an upper surface of the base part. The second electrode film is provided below the second region and on the upper surface of the base part.

In another exemplary embodiment, a plasma processing apparatus is provided. The plasma processing apparatus includes a chamber, the substrate support according to any one of various exemplary embodiments, a radio-frequency power supply, and a bias power supply. The substrate support is accommodated in the chamber. The radio-frequency power supply is configured to generate radio frequency power for generating plasma from a gas in the chamber. The bias power supply is configured to generate bias energy for drawing ions from the plasma into the substrate support. At least one of the radio frequency power and the bias energy is supplied via the base.

In one exemplary embodiment, the radio-frequency power supply and the bias power supply are electrically connected to the base.

In one exemplary embodiment, the bias power supply or another bias power supply may be electrically connected to the edge ring or capacitively coupled to the edge ring.

In one exemplary embodiment, the electrostatic chuck may further include a first bias electrode provided in the first region and a second bias electrode provided in the second region. The radio-frequency power supply may be electrically connected to the base. The bias power supply may be electrically connected to the first bias electrode. A bias power supply or another bias power supply may be electrically connected to the second bias electrode.

In one exemplary embodiment, the substrate support includes the first variable capacitor portion including the one or more first conductor portions described above and the second variable capacitor portion including the one or more second conductor portions. The radio-frequency power supply and the bias power supply may be electrically connected to the base. Another bias power supply may be electrically connected to the one or more second conductor portions.

In one exemplary embodiment, a plasma processing method is provided. In the plasma processing method, the plasma processing apparatus according to any of various exemplary embodiments is used. The plasma processing method includes a step of placing a substrate on a substrate support. The plasma processing method further includes a step of adjusting electrostatic capacitance of the variable capacitor portion. The plasma processing method further includes a step of processing the substrate with plasma generated within the chamber.

Hereinafter, various exemplary embodiments will be described in detail with reference to the drawings. Further, like reference numerals will be given to like or corresponding parts throughout the drawings.

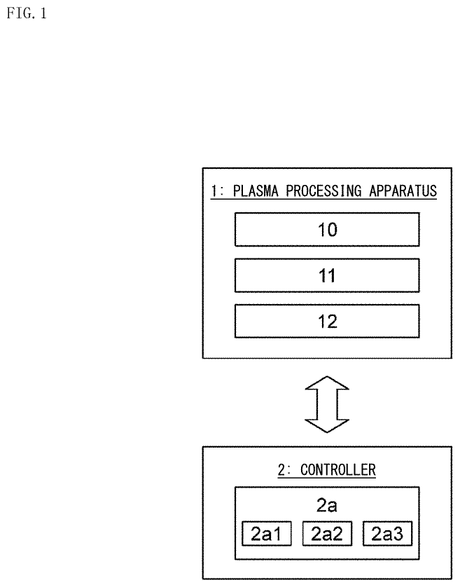

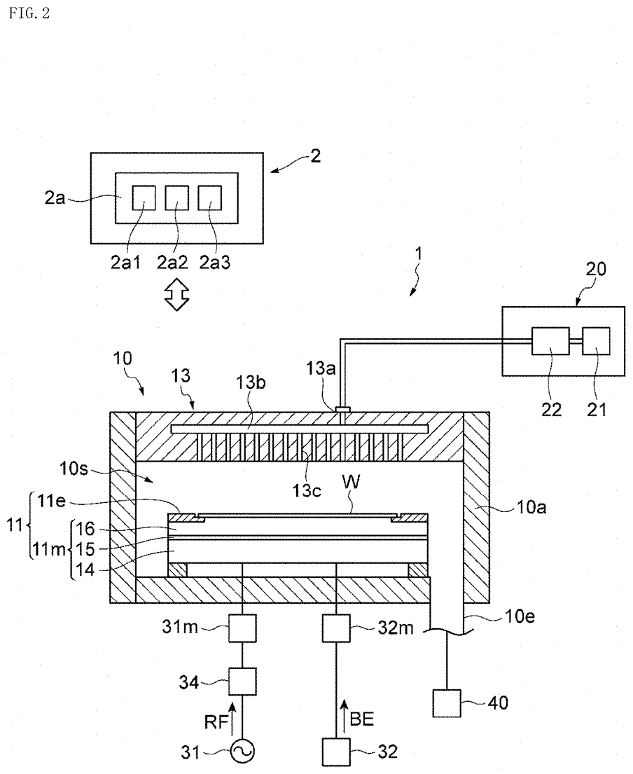

FIGS. 1 and 2 are diagrams schematically illustrating a plasma processing apparatus according to one exemplary embodiment.

In an embodiment, a plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 200 kHz to 150 MHz.

The controller 2 processes computer-executable instructions for instructing the plasma processing apparatus 1 to execute various steps described herein below (e.g., control movement and/or height adjustment of fluid tanks discussed below). The controller 2 may be configured to control the respective components of the plasma processing apparatus 1 to execute the various steps described herein below. In an embodiment, part or all of the controller 2 may be included in the plasma processing apparatus 1. The controller 2 may include circuitry, for example, programmable circuitry in the form of a computer 2a. For example, the computer 2a may include a processor (central processing unit (CPU)) 2a1, a storage 2a2, and a communication interface 2a3. The processor 2a1 may be configured to perform various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, a configuration example of a capacitively coupled plasma processing apparatus as an example of the plasma processing apparatus 1 will be described. The capacitively coupled plasma processing apparatus 1 includes the plasma processing chamber 10, a gas supply 20, a plurality of power supplies, and an exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically insulated from a housing of the plasma processing chamber 10.

The substrate support 11 includes a main body portion 11m and an edge ring 11e. The main body portion 11m is configured to support a substrate W and the edge ring 11e. Although not illustrated, the substrate support 11 may include a temperature control module configured to adjust at least one of the electrostatic chuck 16, the edge ring 11e, and the substrate W to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas to a gap between the rear surface of the substrate W and the upper surface of the substrate support 11.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The plurality of power supplies of the plasma processing apparatus 1 include a direct-current power supply used for holding the substrate W by an electrostatic attraction force, a radio-frequency power supply used for generating plasma, and a bias power supply used for drawing ions from the plasma. The details of the plurality of power supplies will be described later.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

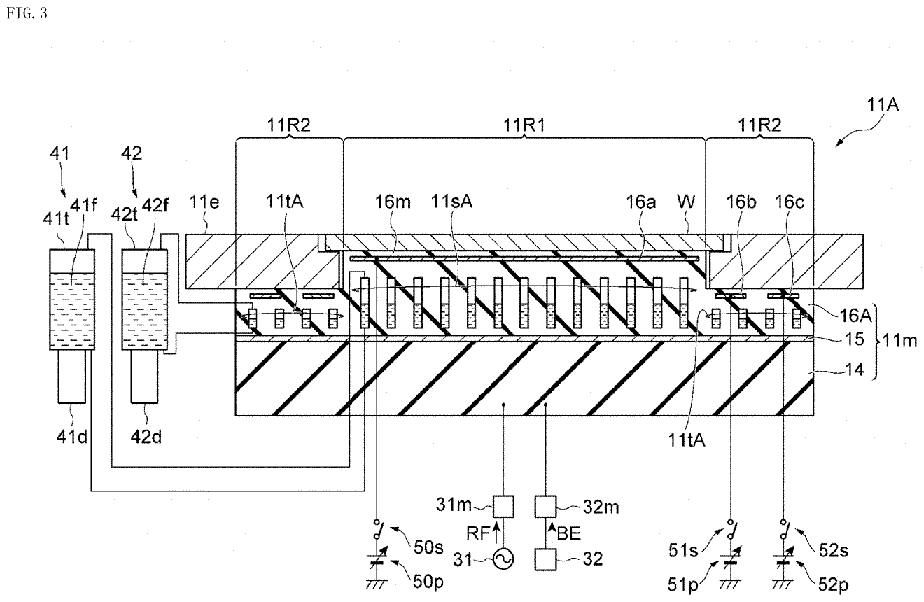

Hereinafter, in addition to FIGS. 1 and 2, FIG. 3 will be referred to. FIG. 3 is a diagram illustrating a substrate support according to an exemplary embodiment. A substrate support 11A illustrated in FIG. 3 can be used as the substrate support 11 of the plasma processing apparatus 1.

The substrate support 11A includes a base 14 and an electrostatic chuck 16A. The base 14 has a substantially disk shape. The base 14 is formed of metal such as aluminum. A radio-frequency power supply 31 is electrically connected to the base 14 via a matcher 31m. Further, a bias power supply 32 is electrically connected to the base 14.

The radio-frequency power supply 31 is configured to generate radio frequency power RF for generating plasma from the gas within the chamber 10. The radio frequency power RF has a frequency in the range of 13 MHz or more and 150 MHz or less. The matcher 31m has a matching circuit for matching the impedance on the load of the radio-frequency power supply 31 with the output impedance of the radio-frequency power supply 31.

The bias power supply 32 is configured to generate bias energy BE for drawing ions from the plasma toward the substrate W. The bias energy BE is electric energy and has a bias frequency in the range of 100 kHz or more and 13.56 MHz or less.

The bias energy BE may be the radio frequency power having the bias frequency, that is, radio frequency bias power. In this case, the bias power supply 32 is electrically connected to the base 14 via the matcher 32m. The matcher 32m has a matching circuit for matching the impedance of the load of the bias power supply 32 with the output impedance of the bias power supply 32.

Alternatively, the bias energy BE may be a pulse, which is periodically generated, of a voltage. A time interval at which the pulse of the voltage is generated, that is, the time length of the period is the reciprocal of the bias frequency. The pulse of the voltage may have a negative polarity or a positive polarity. The pulse of the voltage may be a pulse of a negative direct-current voltage. The pulse of the voltage may have any waveform such as a rectangular wave, a triangular wave, or an impulse wave.

The electrostatic chuck 16A is provided on the base 14. The electrostatic chuck 16A is fixed to the base 14 via a bonding member 15. The bonding member 15 may be an adhesive or a brazing material. The adhesive may be an adhesive containing metal.

The electrostatic chuck 16A has a main body 16m and various electrodes. The main body 16m is formed of a dielectric, such as aluminum oxide or aluminum nitride, and has a substantially disk shape. The various electrodes of the electrostatic chuck 16A are provided in the main body 16m.

The base 14 and the electrostatic chuck 16A provide a first region 11R1 and a second region 11R2.

The first region 11R1 is a central region of the base 14 and the electrostatic chuck 16A, and includes a central part of the main body 16m. The first region 11R1 is substantially circular region in plan view. The second region 11R2 extends in a circumferential direction around the central axes of the substrate support 11A and the electrostatic chuck 16A to surround the first region 11R1. The second region 11R2 is a peripheral region of the base 14 and the electrostatic chuck 16A, and includes a peripheral part of the main body 16m. The second region 11R2 is a ring-shaped region in plan view. The thickness of the electrostatic chuck 16A in the first region 11R1 is larger than the thickness of the electrostatic chuck 16A in the second region 11R2. The vertical directional position of the upper surface of the electrostatic chuck 16A in the first region 11R1 is higher than the vertical directional position of the electrostatic chuck 16A in the second region 11R2.

The first region 11R1 is configured to support the substrate W placed on the first region 11R1. In the first region 11R1, the electrostatic chuck 16A includes a chuck electrode 16a. The chuck electrode 16a is a film formed of a conductive material and is provided in the main body 16m of the electrostatic chuck 16A within the first region 11R1. The chuck electrode 16a may have a substantially circular planar shape. The central axis of the chuck electrode 16a may substantially coincide with the central axis of the electrostatic chuck 16A.

A direct-current power supply 50p is connected to the chuck electrode 16a via a switch 50s. When a direct-current voltage from the direct-current power supply 50p is applied to the chuck electrode 16a, an electrostatic attraction force is generated between the electrostatic chuck 16A in the first region 11R1 and the substrate W. The substrate W is attracted to the electrostatic chuck 16A in the first region 11R1 by the generated electrostatic attraction force and held by the electrostatic chuck 16A.

The second region 11R2 is configured to support the edge ring 11e placed on the second region 11R2. The substrate W is disposed on the first region 11R1 and in a region surrounded by the edge ring 11e. In one embodiment, the electrostatic chuck 16A includes chuck electrodes 16b and 16c in the second region 11R2. Each of the chuck electrodes 16b and 16c is a film formed of a conductive material and is provided in the main body 16m of the electrostatic chuck 16A within the second region 11R2. Each of the chuck electrodes 16b and 16c may extend in the circumferential direction around the central axis of the electrostatic chuck 16A. The chuck electrode 16c may extend outside the chuck electrode 16b.

A direct-current power supply 51p is connected to the chuck electrode 16b via a switch 51s. A direct-current power supply 52p is connected to the chuck electrode 16c via a switch 52s. When a direct-current voltage from the direct-current power supply 51p is applied to the chuck electrode 16b and a direct-current voltage from the direct-current power supply 52p is applied to the chuck electrode 16c, an electrostatic attraction force is generated between the electrostatic chuck 16A in the second region 11R2 and the edge ring 11e. The edge ring 11e is attracted to the electrostatic chuck 16A in the second region 11R2 by the generated electrostatic attraction force and held by the electrostatic chuck 16A.

In various exemplary embodiments, at least one of, or both, the first region 11R1 and the second region 11R2 includes a variable capacitor portion (i.e., a structure that controllably provides a variable electrostatic capacitance) configured to produce a variable electrostatic capacitance.

The electrostatic chuck 16A illustrated in FIG. 3 has variable capacitor portions 11sA and 11tA. The variable capacitor portion 11sA is provided in the main body 16m of the electrostatic chuck 16A within the first region 11R1. The variable capacitor portion 11sA is provided between the chuck electrode 16a and the lower surface of the main body 16m.

The variable capacitor portion 11sA is a cavity provided in the electrostatic chuck 16A within the first region 11R1. The variable capacitor portion 11sA (cavity) may extend in a spiral shape in the electrostatic chuck 16A. The variable capacitor portion 11sA (cavity) is connected to the supply 41. The supply 41 is provided outside the chamber 10. The supply 41 is configured to adjust the amount of fluid 41f in the variable capacitor portion 11sA (cavity).

The fluid 41f may be a dielectric liquid. As the fluid 41f, for example, a liquid such as a fluorocarbon-based liquid (for example, FLUORINERT (registered trademark), Galden, or the like), an insulating oil, super pure water that is an insulating fluid, ethylene glycol, glycerin, or a liquid obtained by dissolving a polymer material in a solvent, a material obtained by adding fine particles of a polymer material or an inorganic material to a liquid or a gas, a semi-fluid such as silicon grease, or the like may be exemplified.

Under the condition that the fluid 41f is a dielectric liquid, the supply 41 may include a tank 41t and an actuator 41d. The tank 41t accommodates the fluid 41f therein. The tank 41t is connected to the variable capacitor portion 11sA (cavity) via a communication pipe and a vent pipe. According to the communication pipe, the position of the liquid surface of the fluid 41f in the variable capacitor portion 11sA in the height direction is the same as the position of the liquid surface of the fluid 41f in the tank 41t in the height direction. Therefore, in response to an instruction by the controller 2, by adjusting the position of the tank 41t in the height direction, the amount of fluid 41f in the variable capacitor portion 11sA can be adjusted. The actuator 41d is configured to move the tank 41t in the vertical direction. The position of the tank 41t in the height direction is adjusted by the movement of the tank 41t in the vertical direction by the actuator 41d.

The variable capacitor portion 11tA is provided in the main body 16m of the electrostatic chuck 16A within the second region 11R2. The variable capacitor portion 11tA is provided between each of the chuck electrodes 16a and 16c and the lower surface of the main body 16m.

The variable capacitor portion 11tA is a cavity provided in the electrostatic chuck 16A within the second region 1182. The variable capacitor portion 11tA (cavity) may extend in a spiral shape in the electrostatic chuck 16A. The variable capacitor portion 11tA (cavity) is connected to the supply 42. The supply 42 is provided outside the chamber 10. The supply 42 is configured to adjust the amount of fluid 42f in the variable capacitor portion 11tA (cavity). The fluid 42f may be a fluid similar to the fluid 41f.

Under a condition the fluid 42f is a dielectric liquid, the supply 42 may include a tank 42t and an actuator 42d. The tank 42t accommodates the fluid 42f therein. The tank 42t is connected to the variable capacitor portion 11tA (cavity) via the communication pipe and the vent pipe. According to the communication pipe, the position of the liquid surface of the fluid 42f in the variable capacitor portion 11tA in the height direction is the same as the position of the liquid surface of the fluid 42f in the tank 42t in the height direction. The amount of fluid 42f in the variable capacitor portion 11tA can be adjusted by adjusting the position of the tank 42t in the height direction. The actuator 42d is configured to move the tank 42t in the vertical direction. The position of the tank 42t in the height direction is adjusted by the movement of the tank 42t in the vertical direction by the actuator 42d.

The substrate support 11A can relatively adjust the electrostatic capacitance of the substrate support 11A below the substrate W and the electrostatic capacitance of the substrate support 11A below the edge ring 11e. Moreover, the substrate support 11A can jointly adjust, or separately adjust, the electrostatic capacitances of the portion of the substrate support 11A below the substrate W and the portion of the substrate support 11A below the edge ring 11e. Accordingly, the state of the plasma on the substrate W and the state of the plasma on the edge ring 11e can be relatively adjusted. For example, it is possible to reduce the difference between the density of plasma above the substrate W and the density of plasma above the edge ring 11e. Further, it is possible to reduce the difference between the position in the height direction of the boundary between the sheath and the plasma above the substrate W and the position in the height direction of the boundary between the sheath and the plasma above the edge ring 11e.

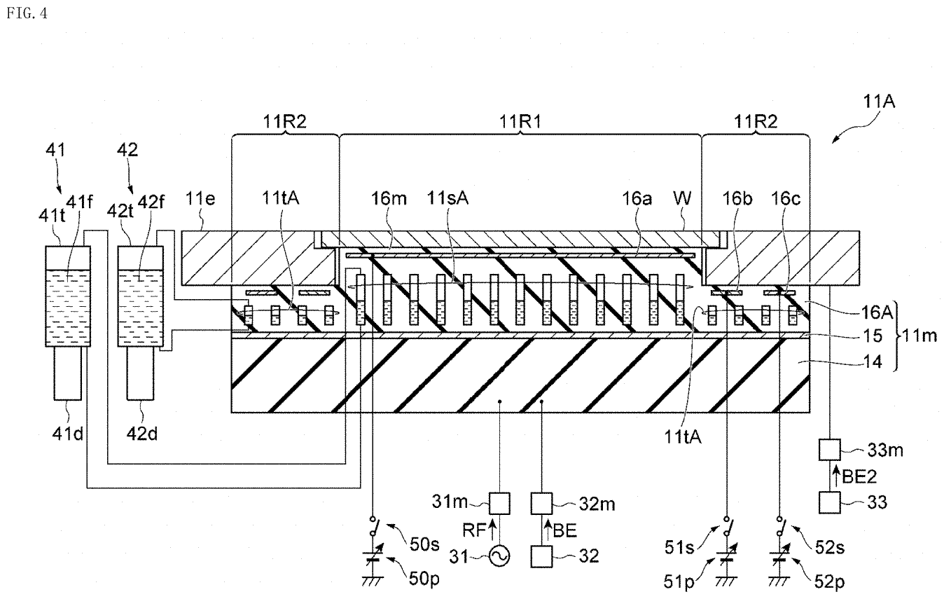

FIG. 4 is a schematic diagram of a plasma processing apparatus according to still another exemplary embodiment. FIG. 4 is a diagram illustrating a substrate support according to another exemplary embodiment. Hereinafter, differences between the embodiment illustrated in FIG. 4 and the embodiment illustrated in FIG. 3 will be described. In the embodiment illustrated in FIG. 4, the bias power supply 33 is electrically connected to the edge ring 11e. The bias power supply 33 is a power supply that generates bias energy BE2. Similar to the bias energy BE, the bias energy BE2 may be the radio frequency bias power, or may be a train of generated pulses of a voltage (fixed or variable). Under the condition the bias energy BE2 is the radio frequency bias power, the bias power supply 33 is electrically connected to edge ring 11e via a matcher 33m.

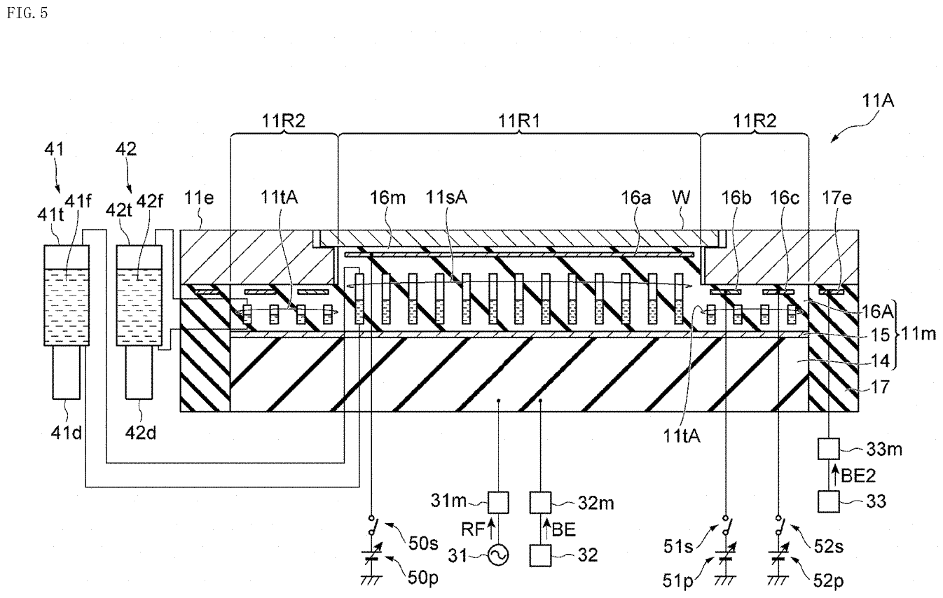

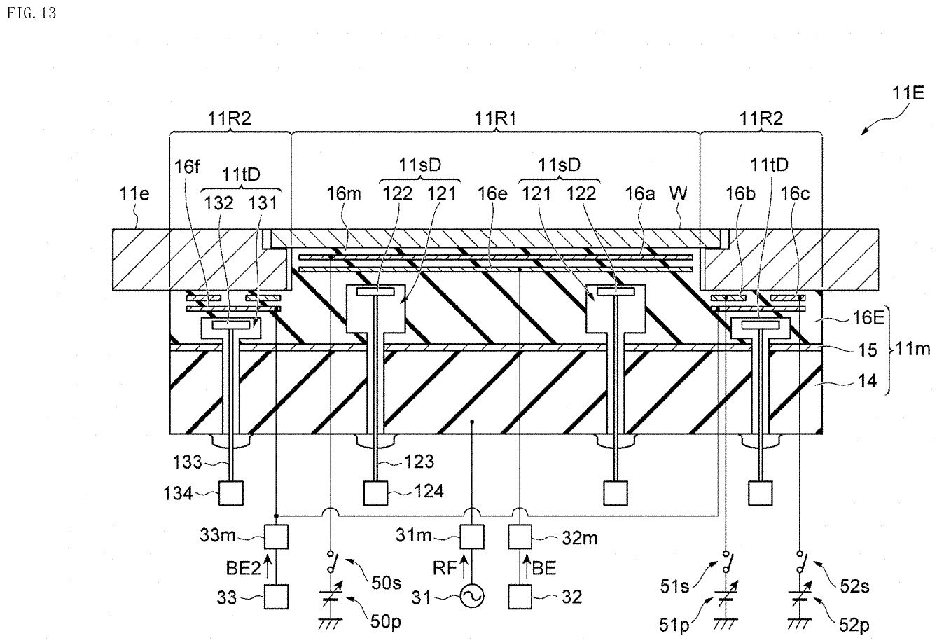

Hereinafter, FIG. 13 will be referred to. FIG. 5 is a diagram illustrating a substrate support according to still another exemplary embodiment. Hereinafter, differences between the embodiment illustrated in FIG. 5 and the embodiment illustrated in FIG. 4 will be described. In the embodiment illustrated in FIG. 5, the bias power supply 33 is capacitively coupled to the edge ring 11e. Specifically, the bias power supply 33 is electrically connected to an electrode 17e capacitively coupled to the edge ring 11e. The electrode 17e may be provided in a dielectric portion 17. The dielectric portion 17 extends along the outer periphery of the substrate support 11A below the edge ring 11e.

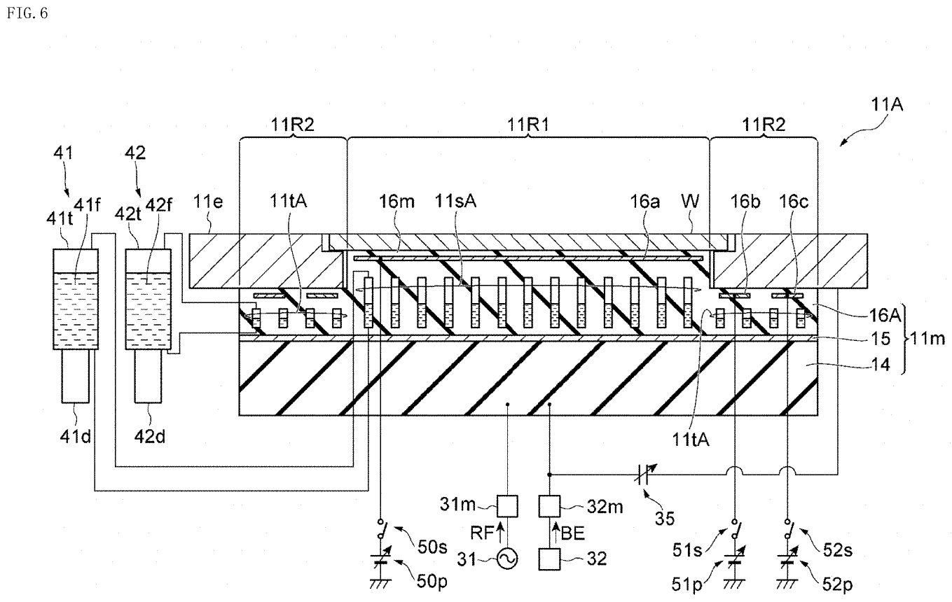

FIG. 6 is a schematic diagram of a plasma processing apparatus according to still another exemplary embodiment. FIG. 6 is a diagram illustrating a substrate support according to still another exemplary embodiment. Hereinafter, differences between the embodiment illustrated in FIG. 6 and the embodiment illustrated in FIG. 3 will be described. In the embodiment illustrated in FIG. 6, the bias power supply 32 is electrically connected to the edge ring 11e in addition to the base 14. In the embodiment illustrated in FIG. 6, the bias energy BE is distributed to the base 14 and the edge ring 11e. The distribution ratio of the bias energy BE between the base 14 and the edge ring 11e is adjusted by an impedance adjuster 35. The impedance adjuster 35 includes, for example, a variable capacitor. The impedance adjuster 35 is connected between the bias power supply 32 and the edge ring 11e. Further, another impedance adjuster may be connected between the bias power supply 32 and the base 14. Alternatively, the impedance adjuster 35 may be connected between the bias power supply 32 and the base 14.

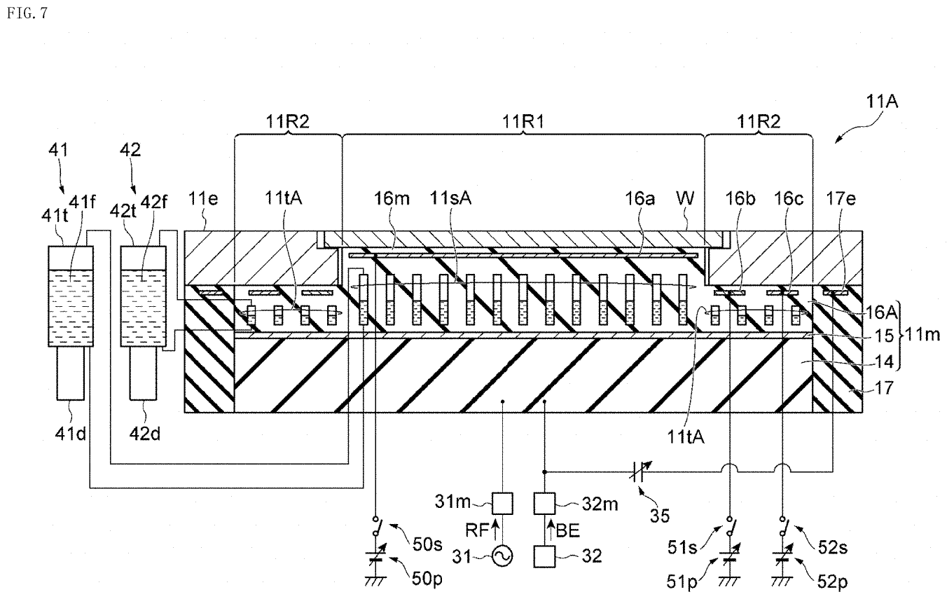

FIG. 7 is a schematic diagram of a plasma processing apparatus according to still another exemplary embodiment. FIG. 7 is a diagram illustrating a substrate support according to still another exemplary embodiment. Hereinafter, differences between the embodiment illustrated in FIG. 7 and the embodiment illustrated in FIG. 6 will be described. In the embodiment illustrated in FIG. 7, the bias power supply 32 is capacitively coupled to the edge ring 11e. Specifically, the bias power supply 32 is electrically connected to the electrode 17e capacitively coupled to the edge ring 11e. The electrode 17e may be provided in a dielectric portion 17. The dielectric portion 17 extends along the outer periphery of the substrate support 11A below the edge ring 11e.

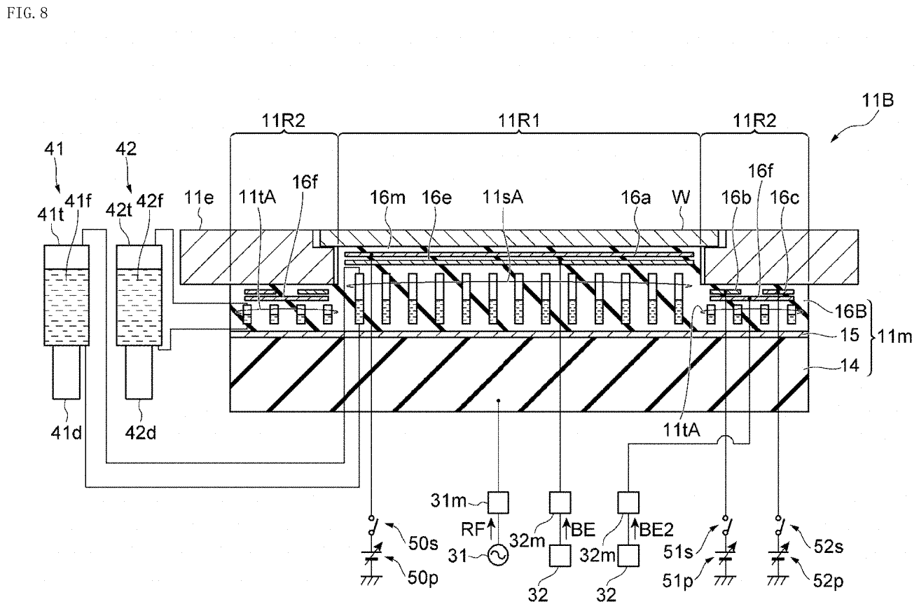

Hereinafter, FIG. 8 will be referred to. FIG. 8 is a diagram illustrating a substrate support according to still another exemplary embodiment. A substrate support 11B illustrated in FIG. 8 may be used as the substrate support 11 of the plasma processing apparatus 1. Hereinafter, the differences between the substrate support 11B illustrated in FIG. 8 and the substrate support 11A will be described. The electrostatic chuck 16B of the substrate support 11B differs from the electrostatic chuck 16A of the substrate support 11A in that the electrostatic chuck 16B includes bias electrodes 16e and 16f.

Each of the bias electrodes 16e and 16f is a film formed of a conductive material. The bias electrode 16e is provided in the main body 16m of the electrostatic chuck 16B within the first region 11R1. The bias electrode 16e may be provided between the chuck electrode 16a and the variable capacitor portion 11sA. The planar shape of the bias electrode 16e may be substantially circular, and the center thereof may be positioned on the central axis of the electrostatic chuck 16B. The bias electrode 16e is electrically connected to the bias power supply 32.

The bias electrode 16f is provided in the main body 16m of the electrostatic chuck 16B within the second region 11R2. The bias electrode 16f may be provided between each of the chuck electrodes 16b and 16c and the variable capacitor portion 11tA. The planar shape of the bias electrode 16f may be a substantially ring shape, and the center thereof may be positioned on the central axis of the electrostatic chuck 16B. The bias power supply 33 is electrically connected to the bias electrode 16f.

The substrate support 11B can apply the bias energy BE having a relatively low frequency to the bias electrode 16e provided near the substrate W. Further, the bias energy BE2 having a relatively low frequency can be applied to the bias electrode 16f provided near the edge ring 11e.

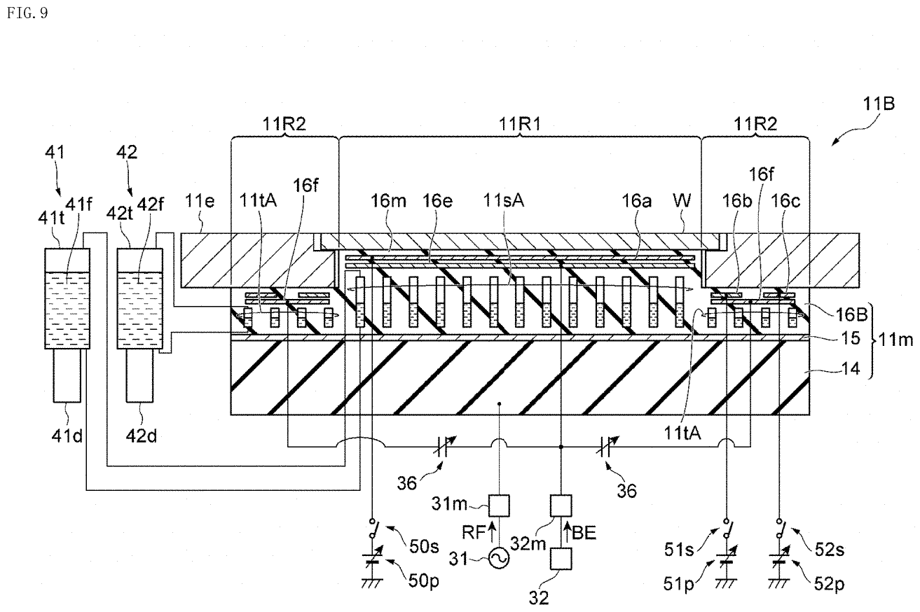

Hereinafter, FIG. 9 will be referred to. FIG. 9 is a diagram illustrating a substrate support according to still another exemplary embodiment. Hereinafter, differences between the embodiment illustrated in FIG. 9 and the embodiment illustrated in FIG. 8 will be described. In the embodiment illustrated in FIG. 9, the bias power supply 32 is electrically connected to the bias electrode 16f in addition to the bias electrode 16e. In the embodiment illustrated in FIG. 9, the bias energy BE is distributed to the bias electrode 16e and the bias electrode 16f. The distribution ratio of the bias energy BE between the bias electrode 16e and the bias electrode 16f is adjusted by an impedance adjuster 36. The impedance adjuster 36 includes, for example, a variable capacitor. the impedance adjuster 36 is connected between the bias power supply 32 and the bias electrode 16f. Further, another impedance adjuster may be connected between the bias power supply 32 and the bias electrode 16e. Alternatively, the impedance adjuster 36 may be connected between the bias power supply 32 and the bias electrode 16e.

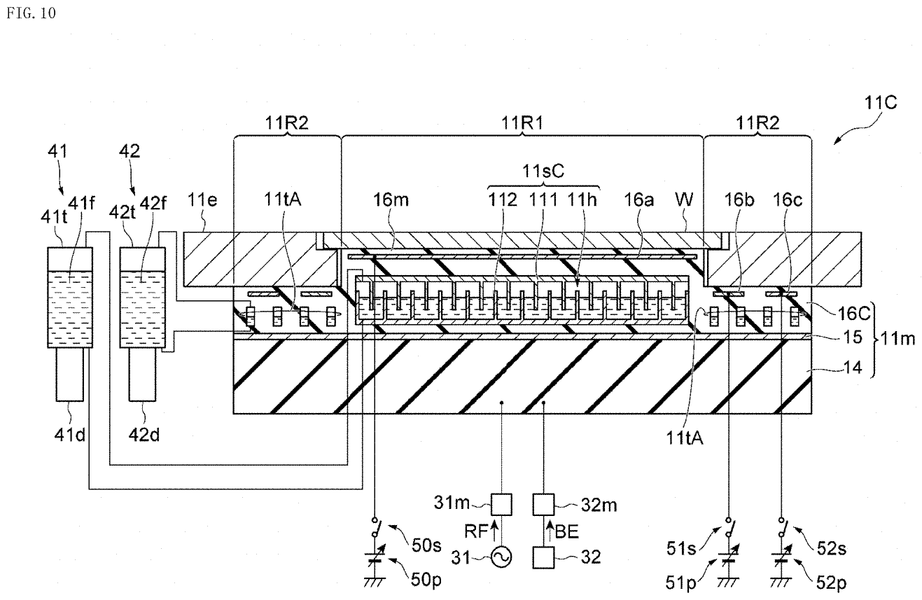

Reference will be made to FIG. 10. FIG. 10 is a diagram illustrating a substrate support according to still another exemplary embodiment. A substrate support 11C illustrated in FIG. 10 may be used as the substrate support 11 of the plasma processing apparatus 1. Hereinafter, the differences between the substrate support 11C illustrated in FIG. 10 and the substrate support 11A will be described. An electrostatic chuck 16C of the substrate support 11C provides a variable capacitor portion 11sC within the first region 11R1, instead of the variable capacitor portion 11sA.

The variable capacitor portion 11sC provides a cavity 11h in the electrostatic chuck 16C within the first region 11R1. The cavity 11h may have a substantially circular planar shape, and the central axis thereof may coincide with the central axis of the electrostatic chuck 16C. The supply 41 is connected to the cavity 11h of the variable capacitor portion 11sC. The amount of fluid 41f in the cavity 11h is adjusted by the supply 41.

The variable capacitor portion 11sC includes a pair of comb-tooth electrodes 111 and 112. The pair of comb-tooth electrodes 111 and 112 are provided in the cavity 11h. The pair of comb-tooth electrodes 111 and 112 are spaced apart from each other. The comb-tooth electrodes 111 are provided above the comb-tooth electrode 112. Each of the plurality of comb teeth of the comb-tooth electrode 111 and the plurality of comb teeth of the comb-tooth electrode 112 extends in the vertical direction and has a substantially tubular shape or a substantially flat-plate shape. The plurality of comb teeth of the comb-tooth electrodes 111 and the plurality of comb teeth of the comb-tooth electrodes 112 are alternately arranged along a radial direction or a horizontal direction.

The variable capacitor portion 11sC may be used instead of the variable capacitor portion 11sA in the embodiments illustrated in FIGS. 4 to 9.

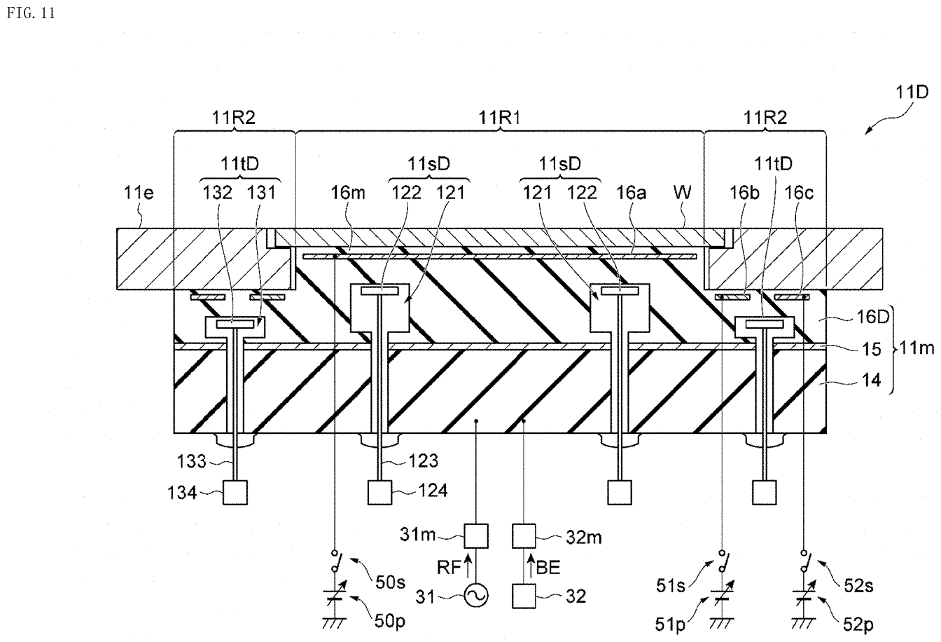

Reference will be made to FIG. 11. FIG. 11 is a diagram illustrating a substrate support according to still another exemplary embodiment. A substrate support 11D illustrated in FIG. 11 may be used as the substrate support 11 of the plasma processing apparatus 1. Hereinafter, the differences between the substrate support 11D illustrated in FIG. 11 and the substrate support 11A will be described. The substrate support 11D includes variable capacitor portions 11sD and 11tD, instead of the variable capacitor portions 11sA and 11tA.

The variable capacitor portion 11sD provides one or more cavities 121 in an electrostatic chuck 16D within the first region 11R1. The variable capacitor portion 11sD includes one or more conductor portions 122. Each of the one or more conductor portions 122 may be a plate formed of a conductor. Each of the one or more conductor portions 122 is provided so as to be movable along the thickness direction of the electrostatic chuck 16D within the one or more cavities 121. The one or more conductor portions 122 are connected to the one or more actuators 124. The one or more actuators 124 are configured to move the one or more conductor portions 122 along the thickness direction of the electrostatic chuck 16D. Each of the one or more conductor portions 122 may be connected to the corresponding actuator 124 via a shaft 123 extending downward from the conductor portion 122. The shaft 123 is formed of a conductor and is electrically connected to the corresponding conductor portion 122 and the base 14.

In the illustrated example, as the one or more cavities 121, a plurality of cavities 121 are provided in the electrostatic chuck 16D within the first region 11R1. The plurality of cavities 121 may be disposed at equal intervals along the circumferential direction with respect to the central axis of the electrostatic chuck 16D. A plurality of conductor portions 122 are provided in the plurality of cavities 121, respectively. The plurality of conductor portions 122 are connected to the plurality of actuators 124, respectively, so as to be movable in the thickness direction of the electrostatic chuck 16D in the plurality of cavities 121. A plurality of shafts 123 extending from the plurality of conductor portions 122 may be connected to the single actuator 124, and the plurality of conductor portions 122 may be moved by the single actuator 124.

The variable capacitor portion 11tD provides one or more cavities 131 in the electrostatic chuck 16D within the second region 11R2. The variable capacitor portion 11tD includes one or more conductor portions 132. Each of the one or more conductor portions 132 may be a plate formed of a conductor. Each of the one or more conductor portions 132 is provided so as to be movable along the thickness direction of the electrostatic chuck 16D within the one or more cavities 131. The one or more conductor portions 132 are connected to one or more actuators 134. The one or more actuators 134 are configured to move the one or more conductor portions 132 along the thickness direction of the electrostatic chuck 16D. Each of the one or more conductor portions 132 may be connected to a corresponding actuator 134 via a shaft 133 extending downward from the conductor portion 132. The shaft 133 is formed of a conductor and is electrically connected to the corresponding conductor portion 132 and the base 14.

In the illustrated example, as the one or more cavities 131, a plurality of cavities 131 are provided in the electrostatic chuck 16D within the second region 11R2. The plurality of cavities 131 may be disposed at equal intervals along the circumferential direction with respect to the central axis of the electrostatic chuck 16D. A plurality of conductor portions 132 are provided in the plurality of cavities 131, respectively. The plurality of conductor portions 132 are connected to the plurality of actuators 134, respectively, so as to be movable in the thickness direction of the electrostatic chuck 16D in the plurality of cavities 131. A plurality of shafts 133 extending from the plurality of conductor portions 132 may be connected to the single actuator 134, and the plurality of conductor portions 132 may be moved by the single actuator 134.

According to the variable capacitor portion 11sD, the electrostatic capacitance of the substrate support 11D below the substrate W is adjusted by adjusting the positions of the one or more conductor portions 122. According to the variable capacitor portion 11tD, the electrostatic capacitance of the substrate support 11D below the edge ring 11e is adjusted by adjusting the positions of the one or more conductor portions 132. Accordingly, the state of the plasma on the substrate W and the state of the plasma on the edge ring 11e can be relatively adjusted.

Further, when the plurality of cavities 121 provided with the plurality of conductor portions 122 therein are arranged along the circumferential direction as in the example illustrated in FIG. 11, it is possible to improve the uniformity of plasma along the circumferential direction by individually controlling the positions of the plurality of conductor portions 122. Further, the plurality of cavities 121 provided with the plurality of conductor portions 122 therein may be further arranged along the radial direction. In this case, the uniformity of the process in the radial direction can be controlled by individually controlling the positions of the plurality of conductor portions 122.

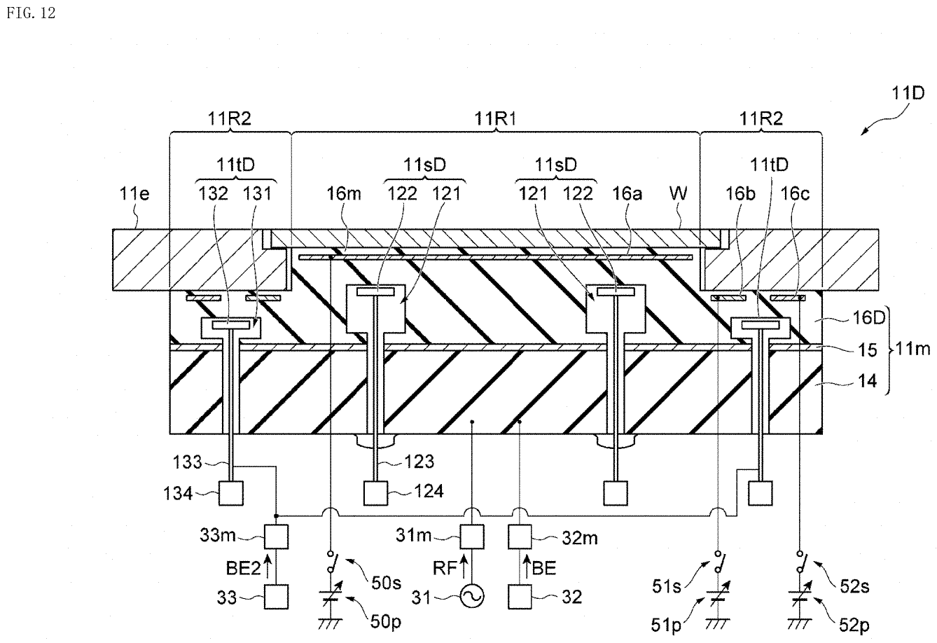

Hereinafter, FIG. 13 will be referred to. FIG. 12 is a diagram illustrating a substrate support according to still another exemplary embodiment. Hereinafter, differences between the embodiment illustrated in FIG. 12 and the embodiment illustrated in FIG. 11 will be described. The embodiment illustrated in FIG. 12 is different from the embodiment illustrated in FIG. 11 in that each shaft 133 is not connected to the base 14, and the bias power supply 33 is electrically connected to the plurality of conductor portions 132 via the plurality of shafts 133.

Hereinafter, FIG. 13 will be referred to. FIG. 13 is a diagram illustrating a substrate support according to still another exemplary embodiment. A substrate support 11E illustrated in FIG. 13 may be used as the substrate support 11 of the plasma processing apparatus 1. Hereinafter, the differences between the substrate support 11E illustrated in FIG. 13 and the substrate support 11D will be described. An electrostatic chuck 16E of the substrate support 11E differs from the electrostatic chuck 16D of the substrate support 11D in that the electrostatic chuck 16E includes the bias electrodes 16e and 16f.

Each of the bias electrodes 16e and 16f is a film formed of a conductive material. The bias electrode 16e is provided in the main body 16m of the electrostatic chuck 16E within the first region 11R1. The bias electrode 16e may be provided between the chuck electrode 16a and the variable capacitor portion 11sD. The planar shape of the bias electrode 16e may be substantially circular, and the center thereof may be positioned on the central axis of the electrostatic chuck 16E. The bias power supply 32 is electrically connected to the bias electrode 16e.

The bias electrode 16f is provided in the main body 16m of the electrostatic chuck 16E within the second region 11R2. The bias electrode 16f may be provided between each of the chuck electrodes 16b and 16c and the variable capacitor portion 11tD. The planar shape of the bias electrode 16f may be a substantially ring shape, and the center thereof may be positioned on the central axis of the electrostatic chuck 16E. The bias power supply 33 is electrically connected to the bias electrode 16f.

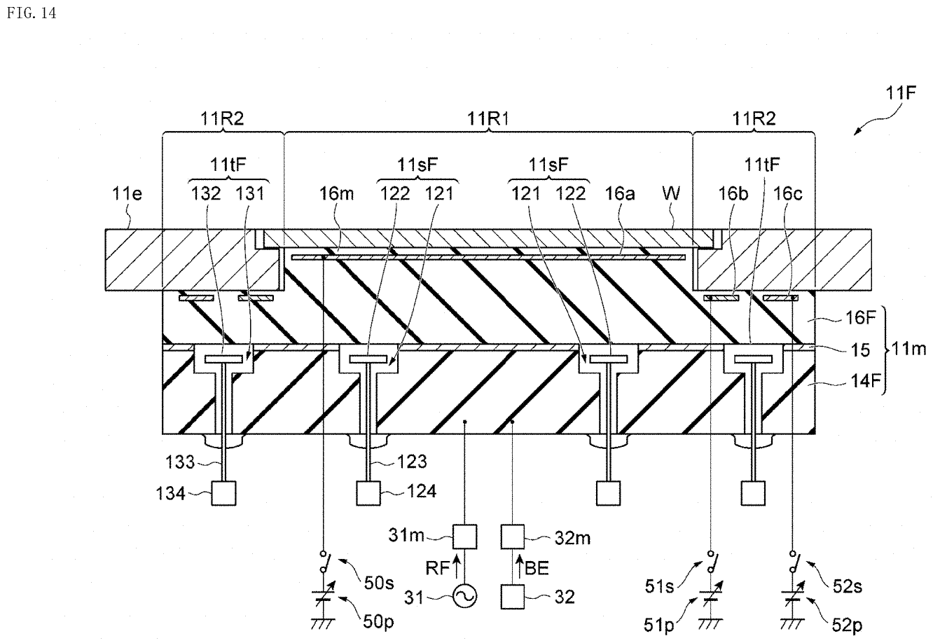

Hereinafter, FIG. 14 will be referred to. FIG. 14 is a diagram illustrating a substrate support according to still another exemplary embodiment. A substrate support 11F illustrated in FIG. 14 can be used as the substrate support 11 of the plasma processing apparatus 1. Hereinafter, the differences between the substrate support 11F illustrated in FIG. 14 and the substrate support 11D will be described. The substrate support 11F includes variable capacitor portions 11sF and 11tF, instead of the variable capacitor portions 11sD and 11tD. The electrostatic chuck 16F of the substrate support 11F is different from the electrostatic chuck 16D of the substrate support 11D in that no variable capacitor portion is formed in the electrostatic chuck 16F.

The variable capacitor portion 11sF provides one or more cavities 121 in the base 14F within the first region 11R1. Similar to the base 14, the base 14F may be formed of metal. The base 14 may be formed of an insulator member or a dielectric member whose surface is covered with metal, and the radio-frequency power supply 31 and the bias power supply 32 may be electrically connected to the surface. Similar to the variable capacitor portion 11sD, the variable capacitor portion 11sF includes one or more conductor portions 122. Each of the one or more conductor portions 122 is provided so as to be movable along the thickness direction of the electrostatic chuck 16F within the one or more cavities 121. The one or more conductor portions 122 are connected to the one or more actuators 124. The one or more actuators 124 are configured to move the one or more conductor portions 122 along the thickness direction of the electrostatic chuck 16F. Each of the one or more conductor portions 122 may be connected to the corresponding actuator 124 via a shaft 123 extending downward from the conductor portion 122. The shaft 123 is formed of a conductor and is electrically connected to the corresponding conductor portion 122 and the base 14F. The shaft 123 may be electrically connected to the corresponding conductor portion 122, the radio-frequency power supply 31, and the bias power supply 32.

In the illustrated example, as the one or more cavities 121, the plurality of cavities 121 are provided in the base 14F within the first region 11R1. The plurality of cavities 121 may be disposed at equal intervals along the circumferential direction with respect to the central axis of the electrostatic chuck 16F. A plurality of conductor portions 122 are provided in the plurality of cavities 121, respectively. The plurality of conductor portions 122 are connected to the plurality of actuators 124, respectively, so as to be movable in the thickness direction of the electrostatic chuck 16F within the plurality of cavities 121. A plurality of shafts 123 extending from the plurality of conductor portions 122 may be connected to the single actuator 124, and the plurality of conductor portions 122 may be moved by the single actuator 124.

A variable capacitor portion 11tF provides one or more cavities 131 in the base 14F within the second region 11R2. Similar to the variable capacitor portion 11tD, the variable capacitor portion 11tF includes one or more conductor portions 132. Each of the one or more conductor portions 132 is provided so as to be movable along the thickness direction of the electrostatic chuck 16F within the one or more cavities 131. The one or more conductor portions 132 are connected to one or more actuators 134. The one or more actuators 134 are configured to move the one or more conductor portions 132 along the thickness direction of the electrostatic chuck 16F. Each of the one or more conductor portions 132 may be connected to a corresponding actuator 134 via a shaft 133 extending downward from the conductor portion 132. The shaft 133 is formed of a conductor and is electrically connected to the corresponding conductor portion 132 and the base 14F.

In the illustrated example, as the one or more cavities 131, the plurality of cavities 131 are provided in the base 14F within the second region 11R2. The plurality of cavities 131 may be disposed at equal intervals along the circumferential direction with respect to the central axis of the electrostatic chuck 16F. A plurality of conductor portions 132 are provided in the plurality of cavities 131, respectively. The plurality of conductor portions 132 are connected to the plurality of actuators 134, respectively, so as to be movable along the thickness direction of the electrostatic chuck 16F within the plurality of cavities 131. A plurality of shafts 133 extending from the plurality of conductor portions 132 may be connected to the single actuator 134, and the plurality of conductor portions 132 may be moved by the single actuator 134.

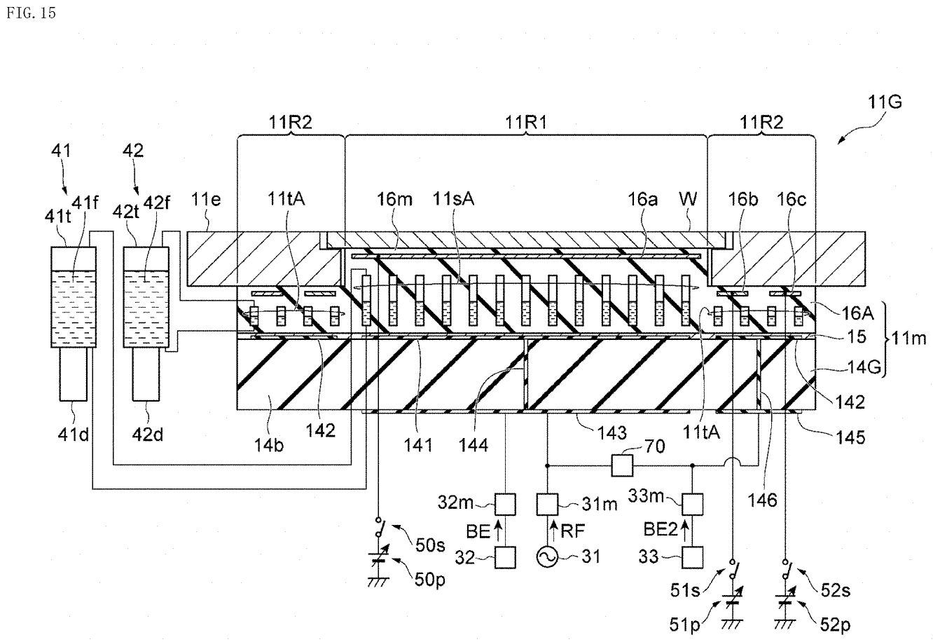

Hereinafter, FIG. 13 will be referred to. FIG. 15 is a diagram illustrating a substrate support according to still another exemplary embodiment. A substrate support 11G illustrated in FIG. 15 may be used as the substrate support 11 of the plasma processing apparatus 1. Hereinafter, the differences between the substrate support 11G and the substrate support 11A will be described.

The substrate support 11G is different from the substrate support 11A in that the substrate support 11G includes a base 14G instead of the base 14. The base 14G includes a base part 14b, a first electrode film 141, and a second electrode film 142. The base part 14b is formed of an insulator or semiconductor, such as SiC or aluminum oxide, and has a substantially disk shape. The first electrode film 141 is provided below the first region 11R1 and on the upper surface of the base part 14b. The second electrode film 142 is provided below the second region 11R2 and on the upper surface of the base part 14b.

As illustrated in FIG. 15, the radio-frequency power supply 31 and the bias power supply 32 are connected to the first electrode film 141. In one embodiment, the radio-frequency power supply 31 and the bias power supply 32 may be connected to the first electrode film 141 via the electrode film 143 and the wiring 144. The electrode film 143 is formed below the first region 11R1 and on the lower surface of the base part 14b. The electrode film 143 is connected to the first electrode film 141 via a wiring 144. The wiring 144 may be a via formed in the base part 14b.

The bias power supply 33 is connected to the second electrode film 142. In one embodiment, the bias power supply 33 may be connected to the second electrode film 142 via an electrode film 145 and a wiring 146. The electrode film 145 is formed below the second region 11R2 and on the lower surface of the base part 14b. The electrode film 145 is connected to the second electrode film 142 via the wiring 146. The wiring 146 may be a via formed in the base part 14b.

The radio-frequency power supply 31 is further connected to the second electrode film 142. An electric path extending between the radio-frequency power supply 31 and the second electrode film 142 is connected to a node on the electric path that connects the bias power supply 32 to the second electrode film 142. A high-pass filter 70 is connected between the node and the radio-frequency power supply 31. The high-pass filter 70 has a characteristic of blocking or attenuating the bias energy BE2 flowing toward the radio-frequency power supply 31, and passes the radio frequency power RF.

In FIG. 15, the radio-frequency power supply 31 and the bias power supply 32 are connected to the same electrode, and the radio-frequency power supply 31 and the bias power supply 33 are connected to the same electrode. However, the bias power supply 32 and the bias power supply 33 may be connected to an electrode different from the electrode to which the radio-frequency power supply 31 is connected. For example, the bias power supply 32 may be electrically connected to an electrode provided below the chuck electrode 16a in the electrostatic chuck 16A and above the variable capacitor portion 11sA. Further, the bias power supply 32 may be electrically connected to the electrode provided below the chuck electrodes 16b and 16c and above the variable capacitor portion 11tA in the electrostatic chuck 16A.

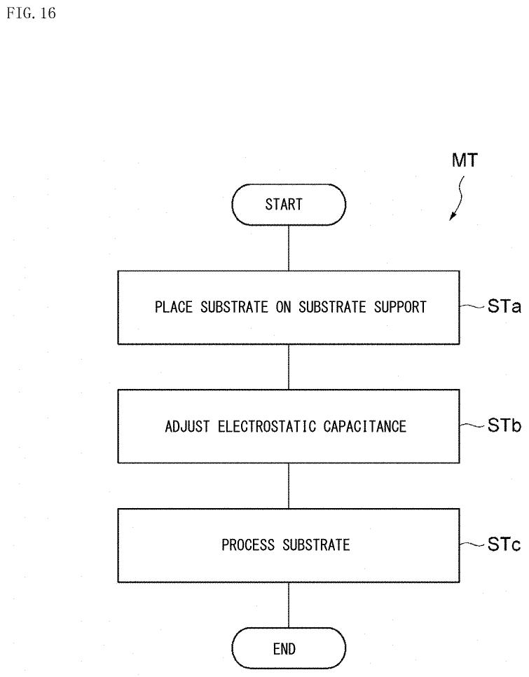

Hereinafter, a plasma processing method according to one exemplary embodiment will be described with reference to FIG. 16. FIG. 16 is a flowchart of a plasma processing method according to an exemplary embodiment. In the plasma processing method illustrated in FIG. 16 (hereinafter, referred to as a “method MT”), the plasma processing apparatus of any of the various exemplary embodiments described above is used.

The method MT starts from step STa. In step STa, the substrate W is placed on the substrate support. The substrate W is disposed on the substrate support and in a region surrounded by the edge ring 11e.

In subsequent step STb, the electrostatic capacitance of the variable capacitor portion of the substrate support is adjusted. When the substrate support 11A, 11B, or 11G is used, the electrostatic capacitance of at least one of the variable capacitor portions 11sA and 11tA is adjusted. When the substrate support 11C is used, the electrostatic capacitance of at least one of the variable capacitor portions 11sC and 11tA is adjusted. When the substrate support 11D or 11E is used, the electrostatic capacitance of at least one of the variable capacitor portions 11sD and 11tD is adjusted. When the substrate support 11F is used, the electrostatic capacitance of at least one of the variable capacitor portions 11sF and 11tF is adjusted.

The electrostatic capacitance of the variable capacitor portion of the substrate support may be determined using a table or function that associates the electrostatic capacitance with an index indicative of the degree of wear and tear of the edge ring 11e. The table or function may be prepared in advance to reduce the difference between the position in the height direction of the boundary between the sheath and the plasma above the substrate W and the position in the height direction of the boundary between the sheath and the plasma above the edge ring 11e.

Subsequent step STc is performed in a state in which the substrate W is placed on the substrate support. Further, step STc is performed after the electrostatic capacitance of the variable capacitor portion of the substrate support is adjusted in step STb. In step STc, the substrate W is processed with the plasma generated in the chamber 10. In step STc, a processing gas is supplied from the gas supply 20 into the chamber 10. Further, the pressure in the chamber 10 is reduced to a designated pressure by the exhaust system 40. Further, the radio frequency power RF from the radio-frequency power supply 31 is supplied. Then, the bias energy BE from the bias power supply 32 is supplied. The bias energy BE2 from the bias power supply 33 may be further supplied. In step STc, the substrate W is processed with chemical species from the plasma generated in the chamber 10.

While various exemplary embodiments have been described above, various additions, omissions, substitutions and changes may be made without being limited to the exemplary embodiments described above. Indeed, the embodiments described herein may be embodied in a variety of other forms.

For example, the electrostatic chuck may not have the chuck electrodes 16b and 16c. Further, the base 14G may be used instead of the base of the substrate support of various embodiments other than the substrate support 11G.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A substrate support comprising:
a base; and
an electrostatic chuck provided on the base, wherein
the base and the electrostatic chuck collectively provide
a first region sized to support a substrate thereon,
a second region that surrounds the first region and sized to support an edge ring thereon, and
at least one of the first region or the second region includes a variable capacitor portion that has a variable electrostatic capacitance that is controllably adjustable.

2. The substrate support according to claim 1, wherein the variable capacitor portion is a cavity provided in the electrostatic chuck, and is connected to a controllable fluid supply that provides a controllable amount of fluid to the variable capacitor portion to adjust an electrostatic capacitance of the variable capacitor portion.

3. The substrate support according to claim 2, wherein the variable capacitor portion includes a pair of comb-tooth electrodes spaced apart from each other in the cavity.

4. The substrate support according to claim 1, wherein
the variable capacitor portion has one or more cavities and one or more conductor portions that are movable along a thickness direction of the electrostatic chuck within the one or more cavities, and
the one or more conductor portions are connected to one or more actuators that move the one or more conductor portions along the thickness direction.

5. The substrate support according to claim 1, wherein a thickness of the electrostatic chuck in the first region is larger than a thickness of the electrostatic chuck in the second region.

6. The substrate support according to claim 4, wherein a thickness of the electrostatic chuck in the first region is larger than a thickness of the electrostatic chuck in the second region.

7. The substrate support according to claim 1, wherein the base is formed of metal.

8. The substrate support according to claim 6, wherein the base is formed of metal.

9. The substrate support according to claim 1, wherein
the base includes:
a base part formed of an insulator,
a first electrode film provided below the first region and on an upper surface of the base part, and
a second electrode film provided below the second region and on the upper surface of the base part.

10. The substrate support according to claim 8, wherein
the base includes:
a base part formed of an insulator,
a first electrode film provided below the first region and on an upper surface of the base part, and
a second electrode film provided below the second region and on the upper surface of the base part.

11. The substrate support according to claim 2, wherein
the variable capacitor portion includes a first variable capacitor as part of the first region, and a second variable capacitor as part of the second region, and
the controllable fluid supply is configured to change an amount of fluid to only one of the first region and the second region so as to adjust a relative electrostatic capacitance between the first variable capacitor and the second variable capacitor.

12. The substrate support according to claim 2, wherein
the variable capacitor portion includes a first variable capacitor as part of the first region, and a second variable capacitor as part of the second region, and
the controllable fluid supply is configured to change respective amounts of the fluid to the first region and the second region so as to adjust a relative electrostatic capacitance between the first variable capacitor and the second variable capacitor.

13. A plasma processing apparatus comprising:
a chamber;
the substrate support provided in the chamber, the substrate support including
a base, and
an electrostatic chuck provided on the base, wherein
the base and the electrostatic chuck collectively provide
a first region sized to support a substrate thereon,
a second region that surrounds the first region and sized to support an edge ring thereon, and
at least one of the first region or the second region includes a variable capacitor portion that has a variable electrostatic capacitance that is controllably adjustable;
a radio-frequency power supply configured to generate radio frequency power to generate plasma from a gas in the chamber; and
a bias power supply configured to generate bias energy to draw ions from the plasma toward the substrate support, wherein
at least one of the radio frequency power and the bias energy is supplied via the base.

14. The plasma processing apparatus according to claim 13, wherein
the bias power supply is configured to generate voltage pulses as a rectangular wave, a triangular wave, or an impulse wave.

15. The plasma processing apparatus according to claim 13, wherein
the substrate support includes a controllable fluid supply that provides a controllable amount of fluid to the variable capacitor portion to adjust an electrostatic capacitance of the variable capacitor portion.

16. The plasma processing apparatus according to claim 15, wherein
the controllable fluid supply includes a fluid tank that is connected to variable capacitor portion via a communication pipe.

17. The plasma processing apparatus according to claim 16, wherein
the controllable fluid supply further includes an actuator that controllably moves a height of the fluid tank to control an amount of the fluid that is passed to the variable capacitor portion via the communication pipe.

18. The plasma processing apparatus according to claim 15, wherein
the variable capacitor portion includes a first variable capacitor as part of the first region, and a second variable capacitor as part of the second region,
the controllable fluid supply includes
a first fluid tank that is connected to the first variable capacitor portion via a first communication pipe, and
a second fluid tank that is connected to the second variable capacitor portion via a second communication pipe.

19. The plasma processing apparatus according to claim 18, wherein
the controllable fluid supply further includes
a first actuator that controllable moves a height of the first fluid tank to control an amount of the fluid that is passed to the first variable capacitor portion via the first communication pipe, and
a second actuator that controllable moves a height of the second fluid tank to control an amount of the fluid that is passed to the second variable capacitor portion via the second communication pipe.

20. A plasma processing method comprising:
placing a substrate on a substrate support that is disposed in a chamber, the substrate support including
a base, and
an electrostatic chuck provided on the base, wherein
the base and the electrostatic chuck collectively provide
a first region sized to support a substrate thereon,
a second region that surrounds the first region and sized to support an edge ring thereon, and
at least one of the first region or the second region includes a variable capacitor portion that has a variable electrostatic capacitance that is controllably adjustable;
adjusting the variable electrostatic capacitance of the variable capacitor portion in at least one of the first region and the second region; and
processing the substrate with plasma generated in the chamber.
